(19) United States
(12) Patent Application Publication
(10) Pub. No.: US 2026/0185772 A1
(43) Pub. Date: Jul. 2, 2026

(54) SUBSTRATE PROCESSING APPARATUS

(71) Applicant: SEMES CO., LTD., Cheonan-si (KR)

(72) Inventors: Hye Bin GWON, Cheonan-si (KR); Hyung Gyu KIM, Ansan-si (KR); Eun Seok KIM, Asan-si (KR); Seung Hoon OH, Cheonan-si (KR)

(73) Assignee: SEMES CO., LTD., Cheonan-si (KR)

(21) Appl. No.: 19/436,380

(22) Filed: Dec. 30, 2025

(30) Foreign Application Priority Data
Dec. 31, 2024 (KR) 10-2024-0202335

(51) Int. Cl. F26B 5/00; H10P 72/00

(52) U.S. Cl. CPC F26B 5/005; H10P 72/0408

(57) ABSTRACT

Disclosed is A substrate processing apparatus. The apparatus includes: an upper vessel in which a first space with an open lower portion is formed; and a substrate holder coupled to the upper vessel, on which a substrate loaded into a treatment space from an external transfer robot is placed, in which the upper vessel includes: an upper wall; and a side wall extending downward from an end of the upper wall, and the substrate holder is coupled to the side wall.

### CROSS-REFERENCE TO RELATED APPLICATION

This application claims priority to and the benefit of Korean Patent Application No. 10-2024-0202335 filed in the Korean Intellectual Property Office on Dec. 31, 2024, the entire contents of which are incorporated herein by reference.

### TECHNICAL FIELD

The present invention relates to a substrate processing apparatus, and more particularly, to an apparatus configured to process a substrate using a supercritical fluid.

### BACKGROUND ART

As the design rule of an integrated circuit device decreases, a process for forming a deep and narrow pattern with a high aspect ratio and the accompanying cleaning and drying processes are required. In particular, methods using supercritical fluids have been proposed in performing predetermined processing processes, for example, processing processes such as etching, cleaning, and drying, on a patterned substrate having a large aspect ratio.

According to an example, the cleaning process cleans an upper surface of the substrate through volatile organic compounds, and the drying process is performed by supplying a fluid containing carbon dioxide (CO₂) in a supercritical state or phase-changing to a supercritical state after supplying the fluid in a gaseous state to remove volatile organic compounds remaining on the substrate.

FIG. 1 is a diagram schematically illustrating a state in which a substrate is processed in a general supercritical chamber. When a chamber 1 is sealed, a fluid is introduced into the chamber through a lower supply line 2, a substrate W is supported by a substrate support 3, and a substrate holder 4 is located near an edge of the substrate. The supplied fluid diffuses into opposite spaces in the chamber along a bottom surface of the substrate support 3, and the fluid flows from the edge region of the substrate W to the central region of the substrate W.

However, in this structure, the substrate holder 4 may interfere with the flow of the fluid, causing an imbalance of the fluid flowing to the substrate W. Unbalance of the fluid flow may directly affect the processing uniformity at the substrate surface. Some regions of the substrate may not be sufficiently in contact with the fluid, and other regions may suffer from excessive exposure to the fluid. This imbalance may seriously affect the quality and performance of the final product.

### SUMMARY OF THE INVENTION

The present invention has been made in an effort to provide a substrate processing apparatus capable of uniformly dry-treating a substrate when the substrate is dry-treated.

The present invention has also been made in an effort to provide a substrate processing apparatus capable of uniformly forming a flow of a fluid flowing on a substrate when the substrate is dry-treated.

The present invention has also been made in an effort to provide a substrate processing apparatus in which a substrate holder supporting an edge region of a substrate does not interfere with the flow of a fluid when the substrate is dry-treated.

The objectives of the present disclosure are not limited thereto and other objectives not stated herein may be clearly understood by those skilled in the art from the following description.

An exemplary embodiment of the present disclosure, A substrate processing apparatus the apparatus comprising: an upper vessel in which a first space with an open lower portion is formed; a lower vessel disposed below the upper vessel, the lower vessel having a second space with an open upper portion, the second space being coupled with the first space to provide a treatment space; a driving unit configured to move the upper vessel and the lower vessel relative to each other; a substrate holder coupled to the upper vessel, on which a substrate loaded into the treatment space from an external transfer robot is placed; a substrate support coupled to the lower vessel and supporting the substrate in the treatment space while processing the substrate; and a fluid supply unit configured to supply a treatment fluid to the treatment space, wherein the upper vessel and the lower vessel are switched in position between an open position and a closed position by the driving unit, the open position is a position where the upper vessel and the lower vessel relatively move to open the treatment space, the closed position is a position where the upper vessel and the lower vessel relatively move to close the treatment space, when the upper vessel and the lower vessel are switched in position from the open position to the closed position, the substrate supported by the substrate holder is handed over to the substrate support, the upper vessel includes: an upper wall; and a side wall extending downward from an end of the upper wall, the first space is a space surrounded by the upper wall and the side wall, and the substrate holder may be coupled to the side wall.

According to the exemplary embodiment of the present invention, wherein the substrate supported by the substrate support in the closed position may be located in the first space.

According to the exemplary embodiment of the present invention, wherein the substrate supported by the substrate support in the closed position may be provided higher than the substrate holder.

According to the exemplary embodiment of the present invention, wherein a lower surface of the side wall may has an inner region in which the substrate holder is installed and an outer region that contacts an upper surface of the side wall of the lower vessel contact in the closed position.

According to the exemplary embodiment of the present invention, wherein the inner region and the outer region are provided at the same height.

According to the exemplary embodiment of the present invention, wherein in the closed position, a lower surface of the side wall may be located higher than an upper surface of the substrate support.

According to the exemplary embodiment of the present invention, wherein in the closed position, the lower surface of the side wall may be located lower than an upper end of a protrusion of the substrate support.

According to the exemplary embodiment of the present invention, wherein in the closed position, the substrate holder may be located lower than the substrate supported by the substrate support.

According to the exemplary embodiment of the present invention, wherein the substrate support may include: a support plate having a disk shape; and a first protrusion protruding upward from the support plate.

According to the exemplary embodiment of the present invention, wherein the plurality of substrate holders is provided and disposed to face each other, the substrate holder may include: a fixing rod having a rod shape extending downward from the side wall; a vertical portion extending downward from the fixing rod and having an arc shape; a horizontal portion extending inward from an end of the vertical portion; and a second protrusion protruding upward from the horizontal portion.

According to the exemplary embodiment of the present invention, wherein when viewed from above, the horizontal portion may be located in a region overlapping the first space.

According to the exemplary embodiment of the present invention, wherein when viewed from above, the substrate holder and the substrate support do not may overlap each other.

According to the exemplary embodiment of the present invention, wherein a width of the first space may be narrower than a width of the second space.

According to the exemplary embodiment of the present invention, wherein the treatment fluid may be a supercritical fluid.

An exemplary embodiment of the present disclosure, A substrate processing apparatus the apparatus comprising: an upper vessel in which a first space with an open lower portion is formed; a lower vessel disposed below the upper vessel, the lower vessel having a second space with an open upper portion, the second space being coupled with the first space to provide a treatment space; a driving unit configured to move the upper vessel and the lower vessel relative to each other; a substrate holder coupled to the upper vessel, on which a substrate loaded into the treatment space from an external transfer robot is placed; a substrate support coupled to the lower vessel and supporting the substrate in the treatment space while processing the substrate; and a fluid supply unit for supplying a supercritical fluid to the treatment space, the upper vessel and the lower vessel are switched in position between an open position and a closed position by the driving unit, the open position is a position where the upper vessel and the lower vessel relatively move to open the treatment space, the closed position is a position where the upper vessel and the lower vessel relatively move to close the treatment space, when the upper vessel and the lower vessel are switched in position from the open position to the closed position, the substrate supported by the substrate holder is handed over to the substrate support, the substrate holder supports an edge region of the substrate loaded into the treatment space, the substrate support supports a central region of the substrate in the treatment space, when viewed from above, the substrate holder and the substrate support do not overlap each other, the upper vessel includes: an upper wall; and a side wall extending downward from an end of the upper wall, the first space is a space surrounded by the upper wall and the side wall, the substrate holder is coupled to the side wall, and in the closed position, the substrate supported by the substrate support is located in the first space, and the substrate holder may be located lower than the substrate supported by the substrate support.

According to the exemplary embodiment of the present invention, wherein in the closed position, a lower surface of the side wall is located higher than an upper surface of the substrate support and may be located lower than an upper end of a protrusion of the substrate support.

According to the exemplary embodiment of the present invention, wherein the lower surface of the side wall has an inner region in which the substrate holder is installed and an outer region that contacts an upper surface of the side wall of the lower vessel in the closed position, and a width of the first space is narrower than a width of the second space.

An exemplary embodiment of the present disclosure, a substrate processing apparatus comprising: an upper vessel in which a first space with an open lower portion is formed; a lower vessel disposed below the upper vessel, the lower vessel having a second space with an open upper portion, the second space being coupled with the first space to provide a treatment space; a driving unit configured to move the upper vessel and the lower vessel relative to each other; a substrate holder coupled to the upper vessel, on which a substrate loaded into the treatment space from an external transfer robot is placed; a substrate support coupled to the lower vessel and supporting the substrate in the treatment space while processing the substrate; and a fluid supply unit for supplying a supercritical fluid to the treatment space, the upper vessel and the lower vessel are switched in position between an open position and a closed position by the driving unit, the open position is a position where the upper vessel and the lower vessel relatively move to open the treatment space, the closed position is a position where the upper vessel and the lower vessel relatively move to close the treatment space, when the upper vessel and the lower vessel are switched in position from the open position to the closed position, the substrate supported by the substrate holder is handed over to the substrate support, the upper vessel includes: an upper wall; and a side wall extending downward from an end of the upper wall, the first space is a space surrounded by the upper wall and the side wall, the substrate holder is coupled to the side wall, and the substrate support includes: a support plate having a disk shape; and a first protrusion protruding upward from the support plate, the plurality of substrate holders is provided and disposed to face each other, the lower surface of the side wall has an inner region in which the substrate holder is installed and an outer region that contacts an upper surface of the side wall of the lower vessel in the closed position, and the substrate holder may include: a fixing rod having a rod shape extending downward from the inner region; a vertical portion extending downward from the fixing rod and having an arc shape; a horizontal portion extending inward from an end of the vertical portion; and a second protrusion protruding upward from the horizontal portion.

According to the exemplary embodiment of the present invention, wherein in the closed position, the substrate supported by the substrate support is located in the first space, and the substrate holder may be located lower than the substrate supported by the substrate support.

According to the exemplary embodiment of the present invention, wherein when viewed from above, the substrate holder and the substrate support do not overlap each other, and a width of the first space may be narrower than a width of the second space.

According to the exemplary embodiment of the present invention, it is possible to uniformly dry-treat a substrate when the substrate is dry-treated.

According to the exemplary embodiment of the present invention, it is possible to uniformly form a flow of a fluid flowing on a substrate when the substrate is dry-treated.

Further, according to the exemplary embodiment of the present invention, a substrate holder supporting an edge region of a substrate does not interfere with the flow of a fluid when the substrate is dry-treated.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a state of processing a substrate in a general drying chamber.

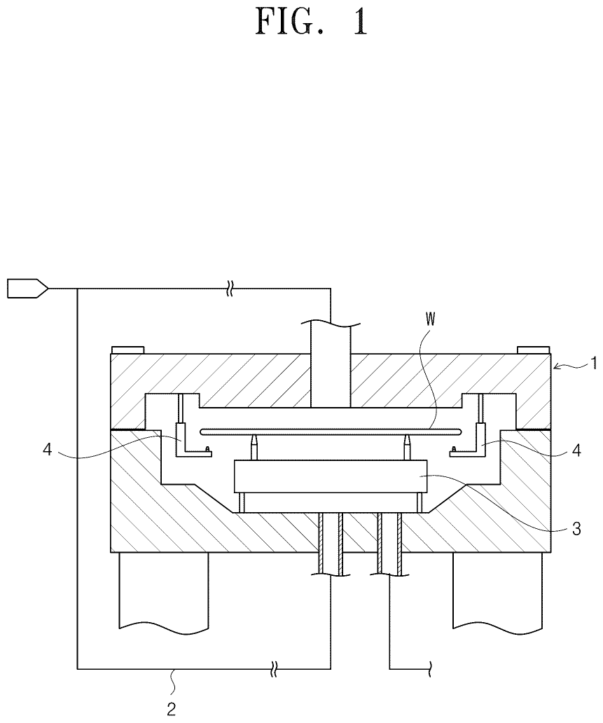

FIG. 2 is a diagram schematically illustrating a substrate processing apparatus according to an exemplary embodiment of the present invention.

FIG. 3 is a diagram schematically illustrating an exemplary embodiment of a liquid treating chamber of FIG. 2.

FIG. 4 is a diagram illustrating a phase change graph of carbon dioxide.

FIG. 5 is a diagram schematically illustrating an exemplary embodiment of a drying chamber of FIG. 2.

FIG. 6 is a diagram illustrating a state in which a substrate loaded into a treatment space is supported by a substrate holder.

FIG. 7 is a diagram illustrating a process of switching from an open position to a closed position.

FIG. 8 is a diagram illustrating a state in which a substrate support supports a substrate in the closed position.

FIG. 9 is a diagram schematically illustrating a substrate processing apparatus according to another exemplary embodiment of the present invention.

FIG. 10 is a diagram schematically illustrating a substrate processing apparatus according to still another exemplary embodiment of the present invention.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical spirit of the present invention may be applied to apparatuses used for treating other types of substrates, other than wafers, as targets to be treated.

Hereinafter, an exemplary embodiment of the present invention will be described with reference to the accompanying drawings.

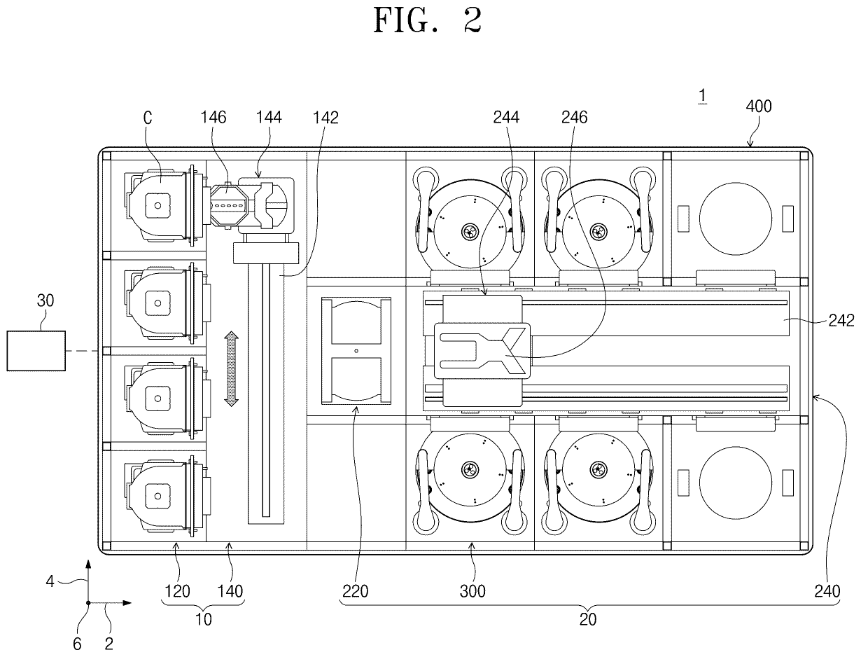

FIG. 2 is a top plan view schematically illustrating a substrate processing apparatus according to an exemplary embodiment of the present invention. Referring to FIG. 2, a substrate processing apparatus 1 includes an index module 10 and a treating module 20. According to an exemplary embodiment, the index module 10 and the treating module 20 are disposed along one direction. Hereinafter, a direction in which the index module 10 and the treating module 20 are arranged is defined as a first direction 2. When viewed from above, a direction perpendicular to the first direction 2 is defined as a second direction 4, and a direction perpendicular to a plane including both the first direction 2 and the second direction 4 is defined as a third direction 6.

The index module 10 transfers a substrate W from a cassette C in which the substrate W is accommodated to the treating module 20 for processing the substrate W. The index module 10 accommodates the substrate W completely processed in the treating module 20 in the cassette C. A longitudinal direction of the index module 10 is provided in the second direction 4. The index module 10 includes a load port 120 and an index frame 140.

The cassette C in which the substrate W is accommodated is seated on the load port 120. Based on the index frame 140, the load port 120 is located at a side opposite to the treating module 20. A plurality of load ports 120 may be provided. The plurality of load ports 120 may be arranged in a line along the second direction 4. The number of load ports 120 may increase or decrease according to the process efficiency and footprint conditions of the treating module 20.

A plurality of slots (not illustrated) is formed in the cassette C. Substrates W may be seated in the slots (not illustrated). A plurality of slots (not illustrated) may be spaced apart from each other in the third direction 6. The substrates W may be seated in the slots (not illustrated), respectively, and accommodated in the cassette C while being horizontally arranged with respect to the ground.

As the cassette C, an airtight container, such as a Front Open Unified Pod (FOUP), may be used. The cassette C may be placed on the load port 120 by a transfer means (not illustrated), such as an overhead transfer, an overhead conveyor, or an automatic guided vehicle, or an operator.

An index rail 142 and an index robot 144 are provided inside the index frame 140. The index rail 142 is provided in the index frame 140 along the second direction 4 in its longitudinal direction. The index robot 144 may transfer the substrate W. The index robot 144 may transfer the

substrate W between the index module 10 and a buffer unit 220 to be described later.

The index robot 144 includes an index hand 146. The substrate W is seated on the index hand 146. The index hand 146 may be provided on the index rail 142 to be movable along the second direction 4. Accordingly, the index hand 146 may be moved forward and backward along the index rail 142. Also, the index hand 146 may be provided to be rotatable with respect to the third direction 6. Also, the index hand 146 may be provided to be vertically movable along the third direction 3. A plurality of index hands 146 may be provided. A plurality of index hands 146 may be provided to be spaced apart from each other in the vertical direction. A plurality of index hands 146 may move forward, backward, and rotate independently of each other.

The controller (not illustrated) controls the substrate processing apparatus 1. The controller may include a process controller formed of a microprocessor (computer) that executes the control of the substrate processing apparatus 1, a user interface formed of a keyboard in which an operator performs a command input operation or the like in order to manage the substrate processing apparatus 1, a display for visualizing and displaying an operation situation of the substrate processing apparatus 1, and the like, and a storage unit storing a control program for executing the process executed in the substrate processing apparatus 1 under the control of the process controller or a program, that is, a treating recipe, for executing the process in each component according to various data and treating conditions. Further, the user interface and the storage unit may be connected to a process controller. The processing recipe may be stored in a storage medium in the storage unit, and the storage medium may be a hard disk, and may also be a portable disk, such as a CD-ROM or a DVD, or a semiconductor memory, such as a flash memory.

The treating module 20 includes a buffer unit 220, a transfer frame 240, a liquid treating chamber 300, and a drying chamber 1000. The buffer unit 220 provides a space in which the substrate W loaded into the treating module 20 and the substrate W unloaded from the treating module 20 stay temporarily. The transfer frame 240 provides a transfer space for transferring the substrate W between the buffer unit 220, the liquid treating chamber 300, and the drying chamber 1000.

The liquid treating chamber 300 performs a liquid treatment process of liquid treating the substrate W by supplying a liquid onto the substrate W. The drying chamber 1000 performs a drying treatment for removing a liquid remaining on the substrate W. The liquid treating chamber 300 and the drying chamber 1000 may perform a cleaning process. The cleaning process may be sequentially performed in the liquid treating chamber 300 and the drying chamber 1000. For example, the liquid treating chamber 300 may process the substrate W by supplying a chemical, a rinse liquid, and/or an organic solvent onto the substrate W. For example, in the drying chamber 1000, a drying treatment for removing a liquid remaining on the substrate W using a supercritical fluid may be performed.

The buffer unit 220 may be disposed between the index frame 140 and the transfer frame 240. The buffer unit 220 may be located at one end of the transfer frame 240. A slot (not illustrated) in which the substrate W is placed is provided in the buffer unit 220. A plurality of slots (not illustrated) is provided. A plurality of slots (not illustrated) may be disposed to be spaced apart from each other along the third direction 6. A front face and a rear face of the buffer unit 220 are opened. The front face is a face facing the index frame 140, and the rear face is a face facing the transfer frame 240. The index robot 144 may approach the buffer unit 220 through the front face, and the transfer robot 244 to be described below may approach the buffer unit 220 through the rear face.

The transfer frame 240 may be provided in a longitudinal direction along the first direction 2. The liquid treating chamber 300 and the drying chamber 1000 may be disposed on opposite sides of the transfer frame 240. The liquid treating chamber 300 and the drying chamber 1000 may be disposed on a side portion of the transfer frame 240. The transfer frame 240 and the liquid treating chamber 300 may be disposed along the second direction 4. Further, the transfer frame 240 and the drying chamber 1000 may be disposed along the second direction 4.

According to an example, the liquid treating chambers 300 are disposed on opposite sides of the transfer frame 240, and the drying chambers 1000 are disposed on opposite sides of the transfer frame 240. The liquid treating chambers 300 may be disposed at positions relatively closer to the buffer unit 220 than the drying chambers 1000. At one side of the transfer frame 240, the liquid treating chambers 300 may be provided in an array of A×B (each of A and B is 1 or a natural number larger than 1) in the first direction 2 and the third direction 6. Here, A is the number of the liquid treating chambers 300 provided in a row along the first direction 2, and B is the number of the liquid treating chambers 300 provided in a row along the third direction 6. For example, when four liquid treating chambers 300 are provided at one side of the transfer frame 240, the liquid treating chambers 300 may be arranged in a 2×2 array. The number of liquid treating chambers 300 may increase or decrease. Unlike the above, the liquid treating chambers 300 may be provided only on one side of the transfer frame 240, and only drying chambers 1000 may be disposed on the other side opposite to one side. Further, the liquid treating chamber 300 and the drying chamber 1000 may be provided as a single layer on one side and opposite sides of the transfer frame 240.

The transfer frame 240 includes a guide rail 242 and a transfer robot 244. The guide rail 242 and the transfer robot 244 are provided inside the transfer frame 240. A longitudinal direction of the guide rail 242 is provided in the first direction 2. The transfer robot 244 may be provided on the guide rail 242 to be able to move linearly along the first direction 2. The transfer robot 244 transfers the substrate W between the buffer unit 220, the liquid treating chamber 300, and the drying chamber 1000.

The transfer robot 244 includes a transfer hand 246 on which the substrate W is placed. The transfer hand 246 may be provided on the guide rail 242 to be movable along the first direction 2. Accordingly, the transfer hand 246 may be moved forward and backward along the guide rail 246. In addition, the transfer hand 246 may be provided to rotate around the third direction 6 and be movable along the third direction 6. A plurality of transfer hands 246 may be provided. A plurality of transfer hands 246 may be provided to be spaced apart from each other in the vertical direction. A plurality of transfer hands 246 may move forward and backward, and rotate independently of each other.

The liquid treating chamber 300 performs a liquid treatment process on the substrate W. For example, the liquid treating chamber 300 may be a chamber that performs a cleaning process to remove byproducts, such as process by-products or particles, attached to the substrate W. The liquid treating chamber 300 may have a different structure depending on the type of process for processing the substrate W. Alternatively, each of the liquid treating chambers 300 may have the same structure.

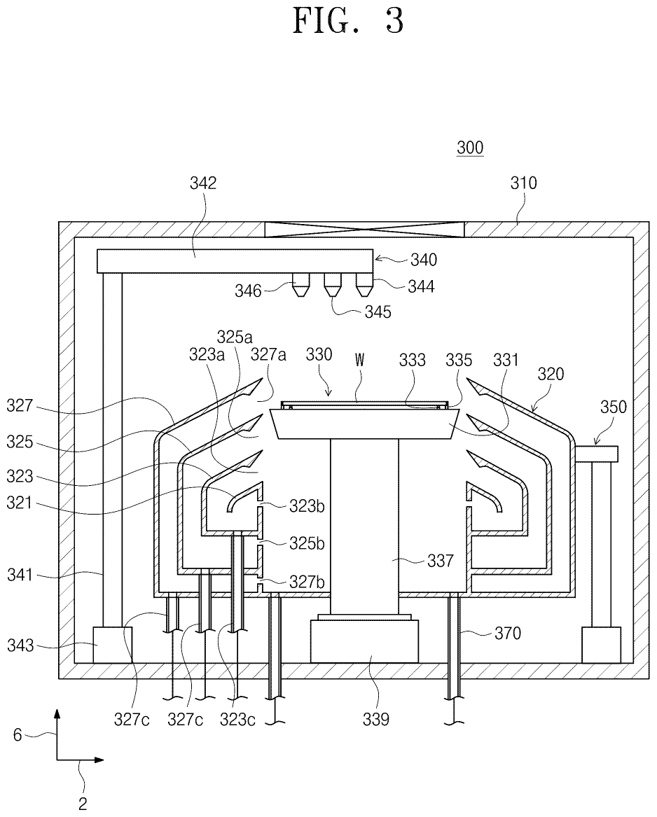

FIG. 3 is a diagram schematically illustrating an exemplary embodiment of the liquid treating chamber of FIG. 2. Referring to FIG. 3, the liquid treating chamber 300 includes a chamber 310, a treating container 320, a support unit 330, and a liquid supply unit 340.

The chamber 310 has an inner space. The chamber 310 is provided in a generally rectangular parallelepiped shape. An opening (not illustrated) is formed at one side of the chamber 310. The opening (not illustrated) functions as an entrance through which the substrate W is loaded in or unloaded from the inner space of the chamber 310 by the transfer robot 244. The treating container 320, the support unit 330, and the liquid supply unit 340 are disposed in the inner space of the chamber 310.

The treating container 320 has a treatment space with an open top. The treating container 320 may be a bowl having a treatment space. The treating container 320 may be provided to surround the treatment space. The treatment space of the treating container 320 is provided as a space in which the support unit 330 described later supports and rotates the substrate W. Further, the treatment space is provided as a space in which the liquid supply unit 340 described later supplies a liquid onto the substrate W and processes the substrate W.

According to an example, the treating container 320 may include a guide wall 321 and a plurality of recovery containers 323, 325, and 327. Each of the recovery containers 323, 325, and 327 separates and recovers a different liquid from among liquids used for the treatment of the substrate W. Each of the recovery containers 323, 325, and 327 has a recovery space of recovering the liquid used for the processing of the substrate.

The guide wall 321 and the recovery containers 323, 325, and 327 are provided in an annular ring shape surrounding the support unit 330. When a liquid is supplied onto the substrate W, a liquid scattered by rotation of the substrate W may be introduced into the recovery space through inlets 323a, 325a, and 327a to be described below of the recovery containers 323, 325, and 327. Different types of liquid may be introduced into each of the recovery containers 323, 325, and 327.

The treating container 320 has a guide wall 321, a first recovery container 323, a second recovery container 325, and a third recovery container 327. The guide wall 321 is provided in a ring shape surrounding the support unit 330. The first recovery container 323 is provided in an annular ring shape surrounding the guide wall 321. The second recovery container 325 is provided in an annular ring shape surrounding the first recovery container 323. The third recovery container 327 is provided in an annular ring shape surrounding the second recovery container 325.

A space between the guide wall 321 and the first recovery container 323 functions as a first inlet 323a through which a liquid is introduced. A space between the first recovery container 323 and the second recovery container 325 functions as a second inlet 325a through which a liquid is introduced. A space between the second recovery container 325 and the third recovery container 327 functions as a third inlet 327a through which a liquid is introduced. The second inlet 325a may be located above the first inlet 323a, and the third inlet 327a may be located above the second inlet 325a. The liquid introduced into the first inlet 323a, the liquid introduced into the second inlet 325a, and the liquid introduced into the third inlet 327a may be different types of liquids.

A space between a lower end of the guide wall 321 and the first recovery container 323 functions as a first outlet 323b through which impurities and fume generated from the liquid are discharged. A space between a lower end of the first recovery container 323 and the second recovery container 325 functions as a second outlet 325b through which impurities and fume generated from the liquid are discharged. A space between a lower end of the second recovery container 325 and the third recovery container 327 functions as a third outlet 327b through which impurities and fume generated from the liquid are discharged. The fume and airflow discharged from the first outlet 323b, the second outlet 325b, and the third outlet 327b are exhausted to the outside of the liquid treating chamber 300 through an exhaust unit 370 to be described later.

Recovery lines 323c, 325c, and 327c extending vertically in a downward direction are connected to bottom surfaces of the recovery containers 323, 325, and 327, respectively. The recovery lines 323c, 325c, and 327c discharge the liquid introduced through the recovery containers 323, 325, and 327, respectively. The discharged treatment liquid may be reused by an external liquid regeneration system (not illustrated).

The support unit 330 supports and rotates the substrate W in the treatment space. The support unit 330 may include a spin chuck 331, a support pin 333, a chuck pin 335, a rotation shaft 337, and a driver 339.

The spin chuck 331 has a top surface that is provided in a generally circular shape when viewed from above. The top surface of the spin chuck 331 may have a larger diameter than the substrate W.

A plurality of support pins 333 is provided. The support pin 333 is disposed on the top surface of the spin chuck 331. The support pin 333 is disposed on the edge of the top surface of the spin chuck 331 to be spaced apart from each other at a predetermined interval. The support pin 333 is formed to protrude upward from the top surface of the spin chuck 331. The support pins 333 are disposed to have an annular ring shape as a whole by a combination thereof. The support pin 333 supports the edge of the back surface of the substrate W so that the substrate W is spaced apart from the top surface of the spin chuck 331 by a predetermined distance.

A plurality of chuck pins 335 is provided. The chuck pin 335 is disposed to be relatively farther from the center region of the spin chuck 331 than the support pin 333. The chuck pin 335 protrudes upward from the top surface of the spin chuck 331. The chuck pin 335 supports a side region of the substrate W so as not to be separated from the correct position in the lateral direction when the substrate W is rotated.

The rotation shaft 337 is coupled to the spin chuck 331. The rotation shaft 337 is coupled to a bottom surface of the spin chuck 331. The rotation shaft 337 may be provided such that a longitudinal direction thereof faces the third direction 6. The rotation shaft 337 is provided to be rotatable by receiving power from the driver 339. The rotation shaft 337 is rotated by the driver 339, and the spin chuck 331 is rotated by the rotation shaft 337. The driver 339 rotates the rotation shaft 337. The driver 339 may vary a rotation speed of the rotation shaft 337. The driver 339 may be a motor that provides driving force. However, the present invention is not limited thereto, and may be variously modified and provided as a known device that provides driving force.

The liquid supply unit 340 supplies a liquid to the substrate W. The liquid supply unit 340 supplies the liquid to the substrate W supported by the support unit 330. The liquid supplied by the liquid supply unit 340 to the substrate W is provided in a plurality of types. The liquid supply unit 340 may include a support rod 341, an arm 342, a driver 343, a first liquid supply nozzle 344, and a second liquid supply nozzle 345.

The support rod 341 is located in the inner space of the housing 310. The support rod 341 is located on one side of the treating container 320 in the inner space. The support rod 341 may have a rod shape whose longitudinal direction faces the third direction 6. The support rod 341 is provided to be rotatable by the driver 343 to be described later.

The arm 342 is coupled to an upper end of the support rod 341. The arm 342 extends vertically from the longitudinal direction of the support rod 341. A longitudinal direction of the arm 342 may be formed in the third direction 6. The first liquid supply nozzle 344, the second liquid supply nozzle 345, and the third liquid supply nozzle 346, which will be described later, may be fixedly coupled to the end of the arm 342.

The arm 342 may be provided to be able to move forward and backward along the longitudinal direction thereof. The arm 342 may be swingably moved by the driver 343 that rotates the support rod 341 via the support rod 341. By rotation of the arm 342, the first liquid supply nozzle 344, the second liquid supply nozzle 345, and the third liquid supply nozzle 346 may also be swing-moved and moved between the process position and the standby position.

The process position may be a position where any one of the first liquid supply nozzle 344, the second liquid supply nozzle 345, and the third liquid supply nozzle 346 faces the substrate W supported by the support member 330. According to an example, the process position may be a position where a center of any one of the first liquid supply nozzle 344, the second liquid supply nozzle 345 faces the center of the substrate W supported by the support member 330. The standby position may be a position where the first liquid supply nozzle 344, the second liquid supply nozzle 345, and the third liquid supply nozzle 346 are all out of the process position.

The driver 343 is coupled with the support rod 341. The driver 343 may be disposed on the bottom surface of the chamber 310. The driver 343 provides driving force for rotating the support rod 341. The driver 343 may be provided as a known motor for providing driving force.

The first liquid supply nozzle 344 supplies a first liquid onto the substrate W. The first liquid supply nozzle 344 may supply the first liquid onto the substrate W supported by the support unit 330. The second liquid supply nozzle 345 supplies a second liquid onto the substrate W. The second liquid supply nozzle 345 may supply the second liquid onto the substrate W supported by the support unit 330. The third liquid supply nozzle 346 supplies a third liquid onto the substrate W. The third liquid supply nozzle 346 may supply the third liquid onto the substrate W supported by the support unit 330.

According to the exemplary embodiment, each of the first liquid, the second liquid, and the third liquid may be any one of a chemical, a rinse liquid, and an organic solvent. For example, the chemical may include diluted sulfuric acid (H₂SO₄), diluted phosphoric acid (P₂O₅), hydrofluoric acid (HF), and ammonium hydroxide (NH₄OH). For example, the rinse liquid may include water or deionized water (DIW). For example, the organic solvent may contain alcohol, such as isopropyl alcohol (IPA). According to the exemplary embodiment, the first liquid may be a chemical. Also, the second liquid may be a rinse liquid. Also, the third liquid may be an organic solvent.

Although the present invention has been described based on the case where in the liquid supply unit 340 according to the exemplary embodiment of the present invention, the first liquid supply nozzle 344, the second liquid supply nozzle 345, and the third liquid supply nozzle 346 are all coupled to the arm 342 as an example, the present invention is not limited thereto. For example, the first liquid supply nozzle 344, the second liquid supply nozzle 345, and the third liquid supply nozzle 346 may each independently have an arm, a support rod, and a driver, and may independently swing and move, and move forward and backward to move between the process position and the standby position.

The lifting unit 350 is disposed in the inner space of the housing 310. The lifting unit 350 adjusts the relative height between the treating container 320 and the support unit 330. The lifting unit 350 may linearly move the treating container 320 in the third direction 6. Accordingly, the heights of the recovery containers 323, 325, and 327 for recovering the liquid are changed according to the type of liquid supplied to the substrate W, and thus the liquids may be separated and recovered. Unlike the above description, the treating container 320 is fixedly installed, and the lifting unit 350 may change the relative height between the support unit 330 and the treating container 320 by moving the support unit 330 in the vertical direction.

The exhaust unit 370 exhausts the impurities generated in the treatment space. Impurities generated when the substrate W is liquid-treated are exhausted by a pressure reducing unit (not illustrated) provided in the exhaust unit 370. The exhaust unit 370 may be coupled to the bottom surface of the treating container 320. For example, the exhaust unit 370 may be disposed in the space between the rotation shaft 337 and the inner side wall of the treating container 320.

The drying chamber 1000 may be a process chamber sealed from an external environment. The drying chamber 1000 removes a liquid remaining on the substrate W using a process fluid. According to an example, the drying chamber 1000 removes the third liquid (e.g., an organic solvent) remaining on the substrate W using a supercritical fluid. In the drying chamber 1000, a supercritical process is performed using the characteristics of the supercritical fluid. Representative examples thereof include a supercritical drying process and a supercritical etching process. Hereinafter, a supercritical process will be described on the basis of a supercritical drying process. However, since this is only for convenience of understanding, the drying chamber 1000 may perform other supercritical processes in addition to the supercritical drying process. According to an exemplary embodiment, supercritical carbon dioxide (scCO2) may be used as the supercritical fluid.

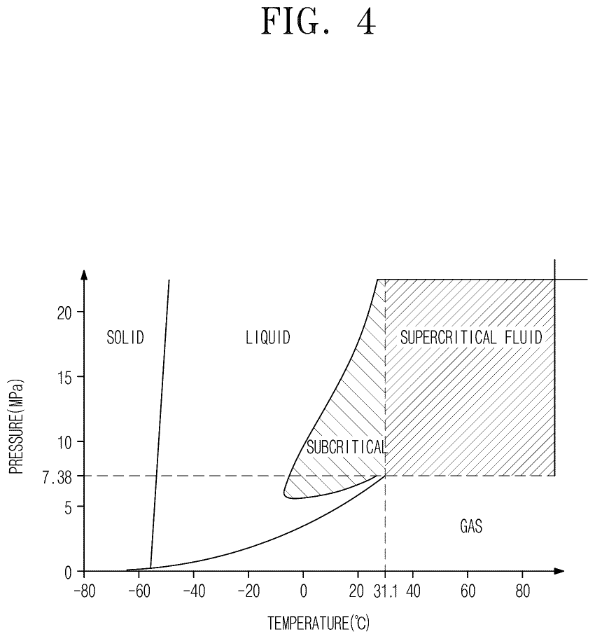

FIG. 4 is a diagram illustrating a phase change graph of carbon dioxide. Referring to FIG. 4, carbon dioxide has advantages in that it has a relatively low critical temperature of 31.1 and a relatively low critical pressure of 7.38 MPa, which makes it easy to bring into a supercritical state, allowing phase changes to be easily controlled by adjusting temperature and pressure, and being inexpensive. In addition, carbon dioxide is harmless to the human body because it is not toxic, and has non-combustible and inert properties. Supercritical carbon dioxide has a diffusion coefficient approximately 10 to 100 times higher than that of water or other organic solvents, so it penetrates quickly, and the organic solvent is quickly replaced. In addition, supercritical carbon dioxide has little surface tension, so it has advantageous physical properties for use in drying the substrate W having a fine circuit pattern. Moreover, supercritical carbon dioxide may be recycled as it is generated as a byproduct of various chemical reactions, and after being used in a supercritical drying process, it may be converted into a gaseous state to separate and reuse organic solvents, thereby imposing a relatively low burden in the aspect of the environmental contamination.

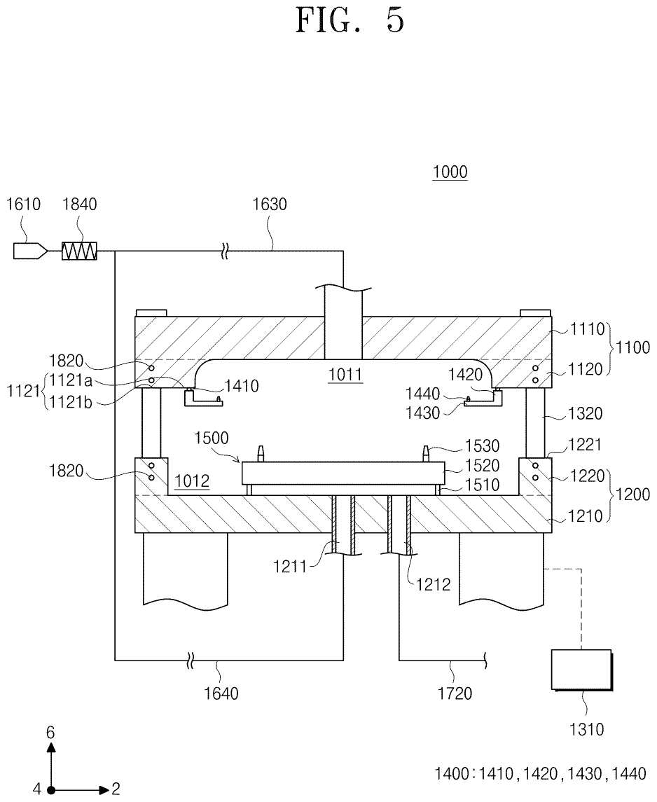

FIG. 5 is a diagram schematically illustrating an exemplary embodiment of the drying chamber of FIG. 2. Referring to FIG. 5, the drying chamber 1000 may include an upper vessel 1100, a lower vessel 1200, a driving unit 1300, a substrate holder 1400, a substrate support 1600, a fluid supply unit 1600, a fluid discharge unit 1670, and a heating unit 1800.

The drying chamber 1000 has a treatment space 1010 therein. A drying process for the substrate W may be performed in the treatment space 1010. The drying chamber 1000 may include an upper vessel 1100 and a lower vessel 1200.

The upper vessel 1100 and the lower vessel 1200 are disposed vertically. According to the exemplary embodiment, the upper vessel 1100 may be located above the lower vessel 1200. The upper vessel 1100 and the lower vessel 1200 may be coupled with each other to define the treatment space 1010. The upper vessel 1100 and the lower vessel 1200 may be coupled with each other to have a generally cylindrical shape. The upper vessel 1100 and the lower vessel 1200 are provided to be relatively movable. The upper vessel 1100 and the lower vessel 1200 are provided to be switchable in position between an open position and a closed position. The open position may be a position to open the treatment space 1010 by separating the upper vessel 1100 and the lower vessel 1200 from each other. The closed position may be a position to seal the treatment space 1010 by making the upper vessel 1100 and the lower vessel 1200 be in contact with each other. A method of driving the upper vessel 1100 and the lower vessel 1200 will be described later.

The upper vessel 1100 may include an upper wall 1110 and a side wall 1120. The upper wall 1110 and the side wall 1120 may be provided integrally. The upper wall 1110 and the side wall 1120 may be combined to define the first space 1011. The first space 1011 may be a space included in the treatment space 1010.

The upper wall 1110 constitutes an upper portion of the upper vessel 1100. An upper supply line 1630 may be connected to the central region of the upper wall 1110, through which the treatment fluid may be supplied to the treatment space 1010. According to an example, an upper supply port 1111 may be formed in a central region of the upper wall 1110, and the upper supply line 1630 may be connected to the upper supply port 1111.

The side wall 1120 has a shape extending vertically downward from the end of the upper wall 1110. The substrate holder 1400 to be described later may be installed on the side wall 1120. According to an example, the substrate holder 1400 may be installed on a lower surface 1121 of the side wall 1120, and more particularly, on an inner region 1121a of the lower surface of the side wall 1120. The bottom surface of the side wall 1120 may include an outer region 1121b in addition to the inner region 1121a. The outer region 1121b may be a region with which the upper surface of the side wall 1120 of the lower vessel is in contact.

The lower vessel 1200 may include a lower wall 1210 and a side wall 1220. The lower wall 1210 and the side wall 1220 may be provided integrally. The lower wall 1210 and the side wall 1220 may be combined to define the second space 1012. The second space 1012 may be a space included in the treatment space 1010.

The lower wall 1210 constitutes a lower portion of the lower vessel 1200. A lower supply line 1640 and a discharge line 1720 may be connected to the lower wall 1210. The lower supply line 1640 may be connected to the center of the lower wall 1210, and the discharge line 1720 may be connected to the lower wall 1210 while being spaced apart from the center of the lower wall 1210 by a predetermined distance. Accordingly, the treatment fluid may be supplied to the treatment space 1010 or the treatment space 1010 may be exhausted. According to an example, a lower supply port 1211 may be formed in a central region of the lower wall 1210, and the lower supply line 1640 may be connected to the lower supply port 1211. Furthermore, the discharge port 1212 may be formed in a region spaced apart from the center of the lower wall 1210, and the discharge line 1720 may be connected to the discharge port 1212. Furthermore, the substrate support 1600 to be described later may be installed on an upper surface of the lower wall 1210.

The side wall 1220 has a shape extending vertically upward from the end of the lower wall 1210. An upper surface 1221 of the side wall 1220 may be in contact with the lower surface 1121 of the side wall 1220 of the upper vessel to seal the treatment space 1010. According to an example, the upper surface 1221 of the side wall 1220 may be in contact with the outer region 1121b of the lower surface of the side wall in the closed position to seal the treatment space 1010.

The driving unit 1300 is provided to move the upper vessel 1100 and the lower vessel 1200 relative to each other. The driving unit 1300 may include a driver 1310 and a lifting rod 1320.

The driver 1310 may be coupled to the lower vessel 1200. According to an exemplary embodiment, as the driver 1310 is coupled to the lower vessel 1200, the lower vessel 1200 may move up and down. Alternatively, a position of the upper vessel 1100 may be fixed. Hereinafter, moving the lower vessel 1200 relative to the upper vessel 1100 will be described as an example.

The driver 1310 may move the lower vessel 1200 to the closed position. The closed position is a position at which the lower vessel 1200 is in contact with the upper vessel 1100 to seal the treatment space 1010. The driver 1310 moves the lower vessel 1200 to the closed position. Accordingly, the lower vessel 1200 is moved upward. The driver 1310 brings the upper vessel 1100 and the lower vessel 1200 into close contact with each other, and the treatment space 1010 is sealed from an external environment. Accordingly, while the drying treatment is performed on the substrate W, the pressure of the treatment space 1010 may be maintained at a high pressure greater than or equal to a threshold pressure.

Also, the driver 1310 may move the lower vessel 1200 to the open position. The open position is a position at which the upper vessel 1100 and the lower vessel 1200 are spaced apart from each other to load the substrate W into the treatment space 1010 or unload the substrate W out of the treatment space 1010. The driver 1310 moves the lower vessel 1200 to the open position. Accordingly, the lower vessel 1200 may descend, and the driver 1310 may separate the upper vessel 1100 and the lower vessel 1200 from each other. When the upper vessel 1100 and the lower vessel 1200 are spaced apart from each other, the treatment space 1010 is opened. When the treatment space 1010 is opened, the transfer robot 244 may enter the treatment space 1010. Accordingly, the transfer robot 244 may load the substrate W into the treatment space 1010 or unload the substrate W out of the treatment space 1010. The substrate W loaded into the treatment space 1010 may be a substrate W on which liquid treatment is completed in the liquid treating chamber 300. For example, the substrate W loaded into the treatment space 1010 may be a substrate W on which an organic solvent remains on an upper surface thereof.

The lifting rod 1320 generates lifting force. For example, the lifting rod 1320 may generate force configured to move in the third direction 6. The lifting rod 1320 may be formed in a direction in which its length direction faces the third direction 6. One end of the lifting rod 1320 may be inserted into the driving unit 1310. The other end of the lifting rod 1320 may be coupled to the upper vessel 1100. The lower vessel 1200 may move in the third direction 6 by the relative lifting motion of the driving unit 1310 and the lifting rod 1320. While the lower vessel 1200 moves in the vertical direction (e.g., the third direction 6), the lifting rod 1320 prevents the upper vessel 1100 and the lower vessel 1200 from moving in the horizontal direction (e.g., the first direction 2 and the second direction 4). The lifting rod 1320 guides the vertical movement direction of the lower vessel 1200. The lifting rod 1320 may prevent the upper vessel 1100 and the lower vessel 1200 from being separated from each other at regular positions.

According to the exemplary embodiment of the present invention described above, the present invention has been described based on the case where the lower vessel 1200 moves in the vertical direction to seal the treatment space 1010 as an example, but the present invention is not limited thereto. For example, each of the upper vessel 1100 and the lower vessel 1200 may move in the vertical direction. Also, the upper vessel 1100 may move in the vertical direction, and the position of the lower vessel 1200 may be fixed.

Also, unlike the above example, the upper vessel 1100 and the lower vessel 1200 may be a single vessel integrally provided. In this case, an opening (not illustrated) through which the substrate W is loaded and unloaded is formed at one side of the vessel, and a door (not illustrated) may be provided at the vessel 1100. A door (not illustrated) may move in the vertical direction to open and close the opening (not illustrated), and the vessel may be maintained in a closed state.

The substrate holder 1400 supports the substrate W in the treatment space 1010. The substrate holder 1400 may be fixedly installed in the upper vessel 1100. The substrate holder 1400 may include a fixing rod 1410, a vertical portion 1420, a horizontal portion 1430, and a first protrusion 1440.

The fixing rod 1410 may be fixedly installed in the upper vessel 1100. The fixing rod 1410 may be installed on the side wall 1120 of the upper vessel. The fixing rod 1410 may be installed in the inner region 1121a of the lower surface of the side wall of the upper vessel. The fixing rod 1410 may be provided in the shape of a rod extending downward from the inner region 1121a. The fixing rod 1410 may be provided such that the longitudinal direction thereof has the vertical direction. Also, a plurality of fixing rods 1410 may be provided. A plurality of fixing rods 1410 is disposed to be spaced apart from each other. A plurality of fixing rods 1410 is disposed so as not to interfere with the substrate W when the substrate W is loaded and unloaded. The vertical portion 1420 may be coupled to a lower end of the fixing rod 1410.

The vertical portion 1420 is coupled to the fixing rod 1410. The vertical portion 1420 may be provided in an arc shape or a straight line shape when viewed from above. Hereinafter, the present invention will be described based on the case where the vertical portion 1420 is provided in an arc shape as an example. An inner diameter of the vertical portion 1420 may be larger than the diameter of the substrate W. The vertical portion 1420 may be provided at a position that does not overlap the path through which the substrate W is loaded when viewed from above. A plurality of vertical portions 1420 may be provided. According to an example, two vertical portions 1420 may be provided. Hereinafter, the present invention will be described based on the case where two vertical portions 1420 are provided as an example. Each of the vertical portions 1420 may be provided at positions facing each other. The respective vertical portions 1420 may be provided in shapes symmetrical to each other. Each of the vertical portions 1420 may be a part of a virtual ring shape. Also, a horizontal portion 1430 may be formed in the vertical portion 1420.

The horizontal portion 1430 has a shape protruding from the vertical portion 1420. The horizontal portion 1430 may extend inward from an end of the vertical portion 1420. The horizontal portion 1430 may extend in a direction toward a space surrounded by the fixing rods 1410. The horizontal portion 1430 may be provided at opposite ends of the vertical portion 1420. A plurality of horizontal portions 1430 may be provided. According to an example, two horizontal portions 1430 may be provided at each of opposite ends of each vertical portion 1420. In addition, the vertical portion 1420 and the horizontal portion 1430 may be integrally provided.

The first protrusion 1440 supports a bottom surface of the substrate W. The first protrusion 1440 is installed on the horizontal portion 1430. The first protrusion 1440 is provided to have a shape protruding upward from an upper surface of the horizontal portion 1430. A plurality of first protrusions 1440 may be provided. According to an example, the number of first protrusions 1440 may be provided as many as the number of horizontal portions 1430.

The substrate support 1500 supports the substrate W in the treatment space 1010. The substrate support 1500 may be fixedly installed in the lower vessel 1200. The substrate support 1500 may include a support rod 1510, a support plate 1520, and a second protrusion 1530.

The support rod 1510 is installed on the upper surface of the lower wall 1210. The support rod 495 is installed to have a longitudinal direction in the vertical direction. The support rod 495 may be provided in a rod shape. The support rod 1510 is installed to protrude from the upper surface of the lower wall 1210. A plurality of support rods 1510 may be provided. A plurality of support rods 1510 is disposed to be spaced apart from each other by a predetermined distance. The support plate 1520 is installed on the support rod 1510.

The support plate 1520 may be provided as a circular plate. The diameter of the support plate 1520 may be smaller than the diameter of the substrate W. The support plate 1520 may be provided in a size that does not interfere with the horizontal portion 1430 when the lower vessel 1200 moves to the closed position. According to an example, the diameter of the support plate 1520 may be smaller than the diameter of a circle formed by the plurality of horizontal portions 1430.

The support plate 1520 may be disposed on the path of the treatment fluid supplied from the lower supply port 1211. When viewed from above, the support plate 1520 may be installed at a position overlapping the lower supply port 1211 and the discharge port 1212 formed in the lower vessel 1200. The support plate 1520 may prevent the treatment fluid supplied from the lower supply port 1211 from being directly discharged toward the substrate W, thereby preventing the bottom surface of the substrate W from being damaged.

When the upper vessel 1100 and the lower vessel 1200 are switched from the open position to the closed position, the substrate support 1500 receives the substrate W placed on the substrate holder 1400. Thereafter, the substrate support 1500 supports the substrate W in the closed position. The substrate holder 1400 is located higher than the substrate support 1500 in the open position. Thereafter, when the upper vessel 1100 and the lower vessel 1200 are switched to the closed position, the substrate holder 1400 is located lower than the substrate support 1600. The substrate W placed on the substrate support 1500 is located in the first space 1011.

The fluid supply unit 1600 supplies a treatment fluid to the treatment space 1010 to be described later. According to an example, the treatment fluid may be a supercritical fluid. Also, the supercritical fluid may be supercritical carbon dioxide (scCO₂).

The fluid supply unit 1600 may include a fluid source 1610, a main supply line 1620, an upper supply line 1630, and a lower supply line 1640.

The fluid supply source 1610 may store and supply a treatment fluid. The fluid supply source 1610 may be provided to increase the temperature and pressure of the treatment fluid. According to an exemplary embodiment, the fluid supply source 1610 may be a reservoir. The fluid supply source 1610 is connected to the main supply line 1620.

The main supply line 1620 may supply the treatment fluid from the fluid supply source 1610 to the upper supply line 1630 and the lower supply line 1640. One end of the main supply line 1620 is connected to the fluid supply source 1610. The other end of the main supply line 1620 may be branched into the upper supply line 1630 and the lower supply line 1640 to be described later.

The upper supply line 1630 supplies a treatment fluid to the treatment space 1010. The upper supply line 1630 supplies a treatment fluid through the upper supply port 1110 in the upper vessel 1100. The upper supply line 1630 is branched from the main supply line 1620. One end of the upper supply line 1630 is connected to the main supply line 1620, and the other end thereof is connected to the upper supply port 1110. The treatment fluid is supplied to the first space 1011 through the upper supply port 1110. Accordingly, the treatment fluid is supplied toward the upper surface of the substrate W placed on the substrate support 1600. Additional devices, such as a pump, a valve, and a filter, which are required to supply the treatment fluid, may be installed in the upper supply line 1630.

The lower supply line 1640 supplies a treatment fluid to the treatment space 1010. The lower supply line 1640 supplies a treatment fluid through the lower supply port 1211 in the lower vessel 1200. The lower supply line 1640 is branched from the main supply line 1620. One end of the lower supply line 1640 is connected to the main supply line 1620, and the other end is connected to the lower supply port 1211. The treatment fluid is supplied to the second space 1012 through the lower supply port 1211. Accordingly, the treatment fluid is supplied toward the bottom surface of the substrate support 1600. Additional devices, such as a pump, a valve, and a filter, required to supply the treatment fluid may be installed in the lower supply line 1640.

The fluid discharge unit 1700 exhausts the atmosphere of the treatment space 1010. Furthermore, the fluid discharge unit 1700 discharges the treatment fluid supplied to the treatment space 1010. The fluid discharge unit 1700 may include a discharge line 1720, a pressure reducing member 1740, and a discharge valve 476.

One end of the discharge line 1720 is connected to the discharge port 1212 formed in the lower vessel 1200. The other end of the discharge line 1720 is connected to the pressure reducing member 1740. The pressure reducing member 1740 may be provided as a pump, an ejector, and the like that provide a negative pressure. The treatment fluid supplied to the treatment space 1010 sequentially passes through the discharge port 1212 and the discharge line 1720 to be discharged to the outside of the treatment space 1010. Also, the discharge valve 476 is installed in the discharge line 1720. The discharge valve 476 may be provided as an opening/closing valve.

The heating unit 1800 changes the temperature of the treatment fluid. According to an exemplary embodiment, the heating unit 1800 may be provided as a heater. The heating unit 1800 may include a first heater 1820 and a second heater 1840.

According to the exemplary embodiment, the first heater 1820 may be buried inside a side wall of at least one of the upper vessel 1100 and the lower vessel 1200. The first heater 1820 may change the temperature of the treatment fluid flowing through the treatment space 1010 by changing the temperature of the treatment space 1010. The first heater 1820 may heat the treatment fluid supplied to the treatment space 1010 to a critical temperature or higher and maintain the treatment fluid in a treatment fluid phase. Furthermore, when the treatment fluid supplied to the treatment space 1010 is liquefied, the first heater 1820 may heat the treatment fluid supplied to the treatment space 1010 so that the treatment fluid is changed to a supercritical phase again.

According to an exemplary embodiment, the second heater 1840 may be installed in the fluid supply unit 1600. For example, the second heater 1840 may be installed in the main supply line 1620. The second heater 1840 may change the internal temperature of the main supply line 1620 to change the temperature of the treatment fluid flowing inside the main supply line 1620. The second heater 1840 may heat the treatment fluid flowing inside the main supply line 1620 to a critical temperature or higher to maintain the treatment fluid phase. In addition, the second heater 1840 may increase the internal temperature of the main supply line 1620 to change the phase of the treatment fluid to a supercritical phase again when the treatment fluid flowing inside the main supply line 1620 is liquefied.

In the above example, the present invention has been described based on the case where the second heater 1840 is installed on the main supply line 1620 as an example, but the present invention is not limited thereto. For example, the second heater 1840 may be installed on at least one of the main supply line 1620, the upper supply line 1630, and the lower supply line 1640.

Hereinafter, a process of supporting the substrate W after the substrate W is loaded into the treatment space 1010 will be described in detail. The substrate supporting process described below may be performed in the drying chamber 1000. Further, a controller, which is not illustrated, may control elements of the drying chamber 1000 to proceed with the substrate supporting process described below.

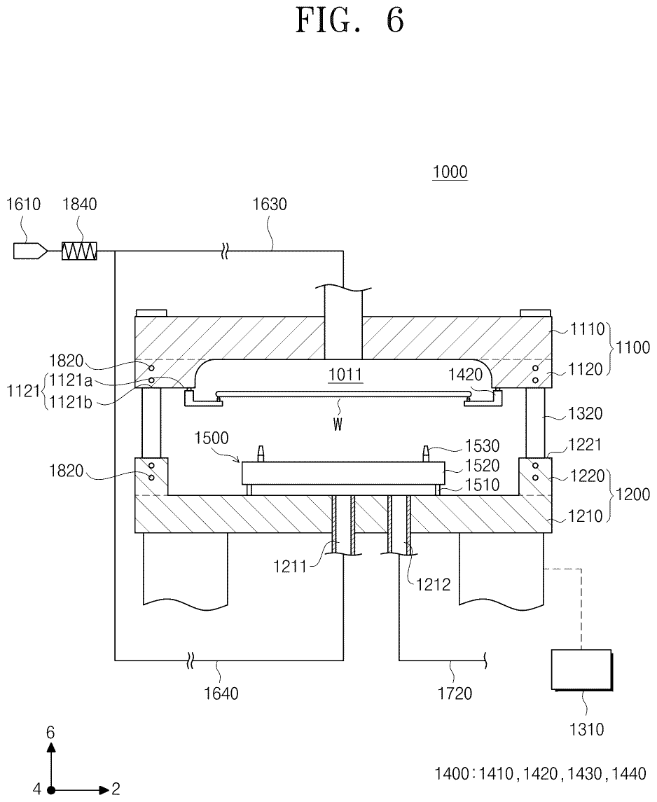

FIG. 6 is a diagram illustrating a state in which a substrate loaded into the treatment space is supported by the substrate holder. Referring to FIG. 6, the upper vessel 1100 and the lower vessel 1200 are moved to the open position by the driving unit 1300. Accordingly, the treatment space 1010 is opened, and the transfer robot enters and loads the substrate W. Since the substrate holder 1400 is located above the substrate support 1500 in the open position, the substrate W may be loaded into the treatment space 1010 without interference from the substrate support 1500.

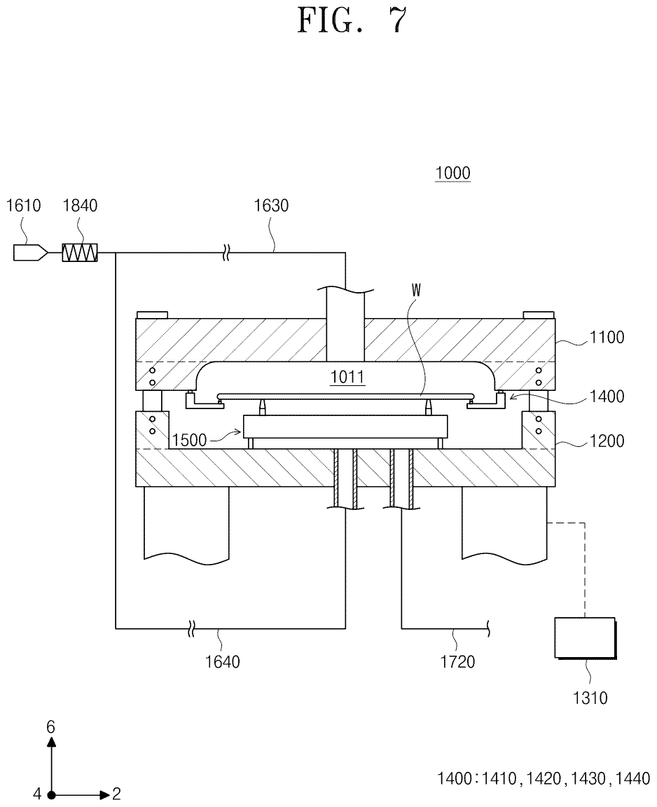

FIG. 7 is a diagram illustrating a process of switching from an open position to a closed position. Referring to FIG. 7, when the upper vessel 1100 and the lower vessel 1200 are switched in position from the open position to the closed position, the distance between the substrate holder 1400 and the substrate support 1500 is gradually decreased. Since the height of the substrate W placed on the substrate support 1500 in the closed position is designed to be higher than the substrate holder 1400, the substrate support 1500 contacts the substrate W placed on the substrate holder 1400 when the upper vessel 1100 and the lower vessel 1200 are switched in position from the open position to the closed position. Since the substrate support 1500 and the substrate holder 1400 are provided so as not to overlap each other when viewed from above, interference between the two components may be avoided when the two components move up and down.

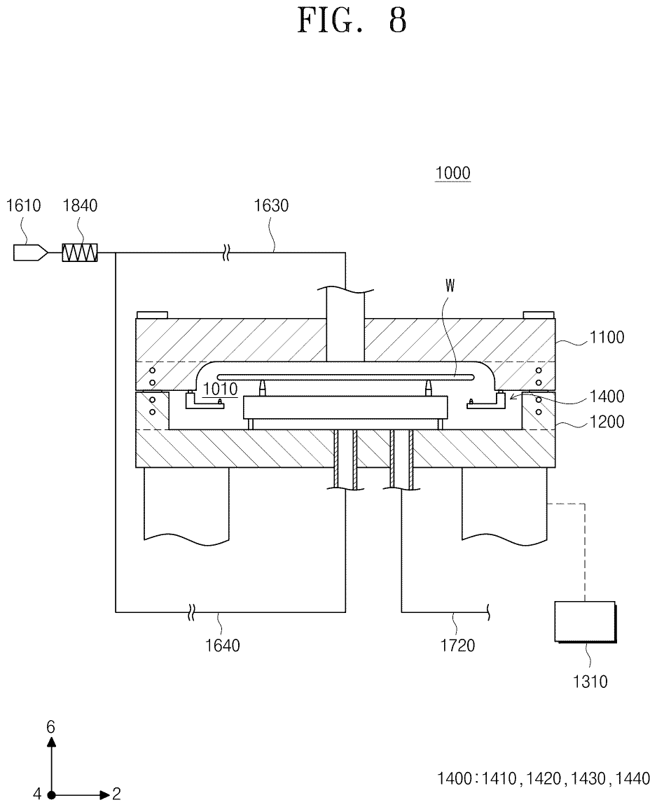

FIG. 8 is a diagram illustrating a state in which the substrate support supports a substrate in the closed position. Referring to FIG. 8, the substrate support 1500 supports the substrate W in in the closed position, and the substrate W is positioned in the first space 1011. Since the substrate holder 1400 is installed at a lower end portion of the side wall 1120 of the upper vessel, the substrate holder 1400 is positioned in the second space 1012. Accordingly, the substrate holder 1400 is positioned lower than the substrate W supported by the substrate support 1500 in the closed position. Furthermore, the substrate support 1400 is spaced apart from the substrate W by a predetermined distance in the closed position. Interference of the flow of the treatment fluid toward the substrate W by the substrate holder 1400 may be minimized. The treatment fluid flows uniformly to the substrate W without interference from the substrate holder 1400, so that the substrate W may be uniformly processed by the treatment fluid.

According to the exemplary embodiment of the present invention, since the substrate holder 1400 is positioned lower than the substrate W placed on the substrate support 1500 and the substrate W is positioned in the first space 1011, the treatment fluid may flow uniformly to the substrate W without interference from the substrate holder 1400. The treatment fluid flows uniformly over the substrate W, and thus the processing uniformity of the substrate W may be improved.

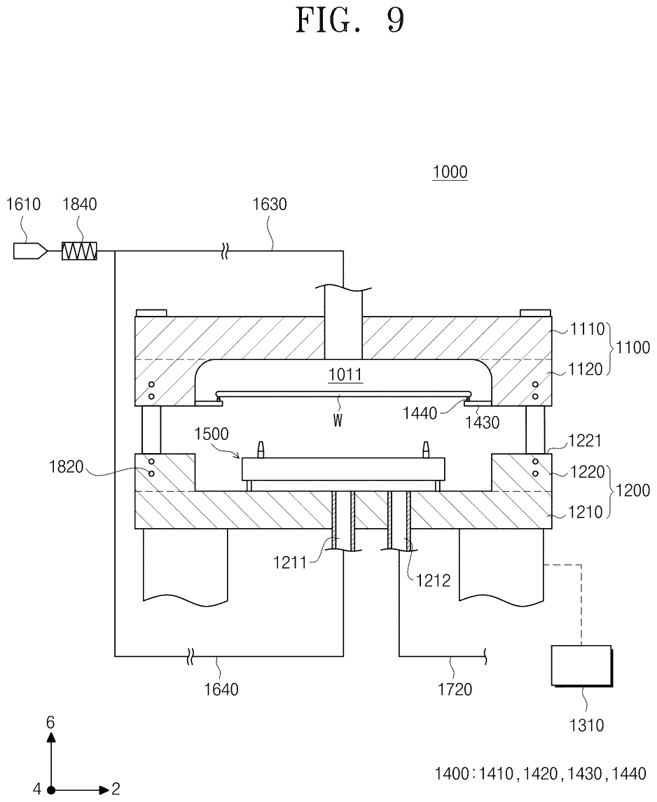

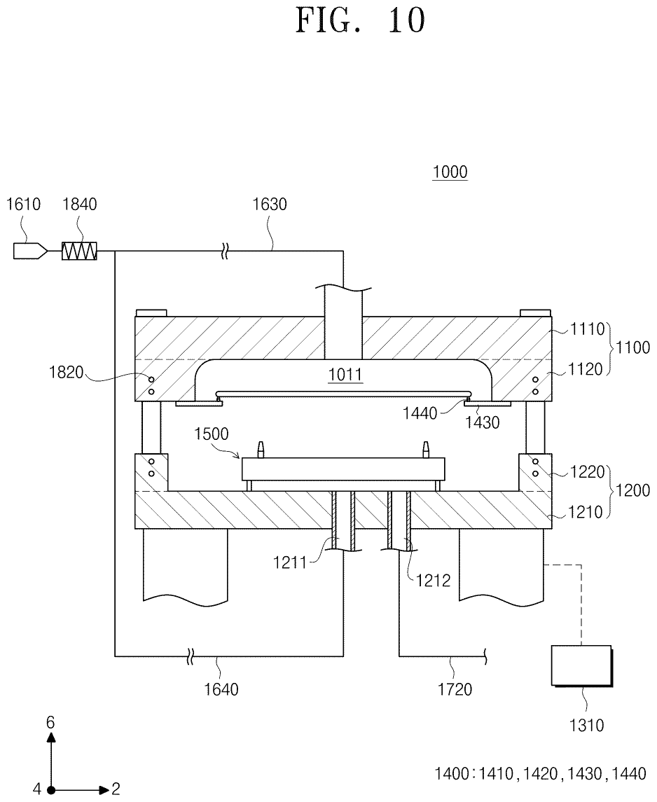

In the above-described example, the present invention has been described based on the case where the substrate holder 1400 includes the fixing rod 1410, the vertical portion 1420, the horizontal portion 1430, and the first protrusion 1440 as an example. However, the present invention is not limited thereto, and the substrate holder 1400 may include only the horizontal portion 1430 and the first protrusion 1440 as illustrated in FIGS. 9 and 10. Referring to FIG. 9, the horizontal portion 1430 may be installed on the inner surface of the side wall of the upper vessel. In this case, the lower surface 1121 of the side wall of the upper vessel may be provided to have the same width as the upper surface 1221 of the side wall of the lower vessel. Referring to FIG. 10, the horizontal portion 1430 may be installed in the inner region 1121a of the side wall of the upper vessel 1100.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A substrate processing apparatus, the apparatus comprising:
an upper vessel in which a first space with an open lower portion is formed;
a lower vessel disposed below the upper vessel, the lower vessel having a second space with an open upper portion, the second space being coupled with the first space to provide a treatment space;
a driving unit configured to move the upper vessel and the lower vessel relative to each other;
a substrate holder coupled to the upper vessel, on which a substrate loaded into the treatment space from an external transfer robot is placed;
a substrate support coupled to the lower vessel and supporting the substrate in the treatment space while processing the substrate; and
a fluid supply unit configured to supply a treatment fluid to the treatment space,
wherein the upper vessel and the lower vessel are switched in position between an open position and a closed position by the driving unit,
the open position is a position where the upper vessel and the lower vessel relatively move to open the treatment space,
the closed position is a position where the upper vessel and the lower vessel relatively move to close the treatment space,
when the upper vessel and the lower vessel are switched in position from the open position to the closed position, the substrate supported by the substrate holder is handed over to the substrate support,
the upper vessel includes:
an upper wall; and
a side wall extending downward from an end of the upper wall,
the first space is a space surrounded by the upper wall and the side wall, and
the substrate holder is coupled to the side wall.

2. The apparatus of claim 1, wherein the substrate supported by the substrate support in the closed position is located in the first space.

3. The apparatus of claim 1, wherein the substrate supported by the substrate support in the closed position is provided higher than the substrate holder.

4. The apparatus of claim 1, wherein a lower surface of the side wall has an inner region in which the substrate holder is installed and an outer region that contacts an upper surface of the side wall of the lower vessel contact in the closed position.

5. The apparatus of claim 4, wherein the inner region and the outer region are provided at the same height.

6. The apparatus of claim 1, wherein in the closed position, a lower surface of the side wall is located higher than an upper surface of the substrate support.

7. The apparatus of claim 6, wherein in the closed position, the lower surface of the side wall is located lower than an upper end of a protrusion of the substrate support.

8. The apparatus of claim 7, wherein in the closed position, the substrate holder is located lower than the substrate supported by the substrate support.

9. The apparatus of claim 1, wherein the substrate support includes:
a support plate having a disk shape; and
a first protrusion protruding upward from the support plate.

10. The apparatus of claim 9, wherein the plurality of substrate holders is provided and disposed to face each other,
the substrate holder includes:
a fixing rod having a rod shape extending downward from the side wall;
a vertical portion extending downward from the fixing rod and having an arc shape;
a horizontal portion extending inward from an end of the vertical portion; and
a second protrusion protruding upward from the horizontal portion.

11. The apparatus of claim 10, wherein when viewed from above, the horizontal portion is located in a region overlapping the first space.

12. The apparatus of claim 11, wherein when viewed from above, the substrate holder and the substrate support do not overlap each other.

13. The apparatus of claim 1, wherein a width of the first space is narrower than a width of the second space.

14. The apparatus of claim 1, wherein the treatment fluid is a supercritical fluid.

15. A substrate processing apparatus, the apparatus comprising:
an upper vessel in which a first space with an open lower portion is formed;
a lower vessel disposed below the upper vessel, the lower vessel having a second space with an open upper portion, the second space being coupled with the first space to provide a treatment space;
a driving unit configured to move the upper vessel and the lower vessel relative to each other;
a substrate holder coupled to the upper vessel, on which a substrate loaded into the treatment space from an external transfer robot is placed;
a substrate support coupled to the lower vessel and supporting the substrate in the treatment space while processing the substrate; and
a fluid supply unit configured to supply a supercritical fluid to the treatment space,
the upper vessel and the lower vessel are switched in position between an open position and a closed position by the driving unit,
the open position is a position where the upper vessel and the lower vessel relatively move to open the treatment space,
the closed position is a position where the upper vessel and the lower vessel relatively move to close the treatment space,
when the upper vessel and the lower vessel are switched in position from the open position to the closed position, the substrate supported by the substrate holder is handed over to the substrate support,
the substrate holder supports an edge region of the substrate loaded into the treatment space,
the substrate support supports a central region of the substrate in the treatment space,
when viewed from above, the substrate holder and the substrate support do not overlap each other,
the upper vessel includes:
an upper wall; and
a side wall extending downward from an end of the upper wall,
the first space is a space surrounded by the upper wall and the side wall,
the substrate holder is coupled to the side wall, and
in the closed position, the substrate supported by the substrate support is located in the first space, and the substrate holder is located lower than the substrate supported by the substrate support.

16. The apparatus of claim 15, wherein in the closed position, a lower surface of the side wall is located higher than an upper surface of the substrate support and is located lower than an upper end of a protrusion of the substrate support.

17. The apparatus of claim 16, wherein the lower surface of the side wall has an inner region in which the substrate holder is installed and an outer region that contacts an upper surface of the side wall of the lower vessel in the closed position, and
a width of the first space is narrower than a width of the second space.

18. A substrate processing apparatus comprising:
an upper vessel in which a first space with an open lower portion is formed;
a lower vessel disposed below the upper vessel, the lower vessel having a second space with an open upper portion, the second space being coupled with the first space to provide a treatment space;
a driving unit configured to move the upper vessel and the lower vessel relative to each other;
a substrate holder coupled to the upper vessel, on which a substrate loaded into the treatment space from an external transfer robot is placed;
a substrate support coupled to the lower vessel and supporting the substrate in the treatment space while processing the substrate; and
a fluid supply unit configured to supply a supercritical fluid to the treatment space,
the upper vessel and the lower vessel are switched in position between an open position and a closed position by the driving unit,
the open position is a position where the upper vessel and the lower vessel relatively move to open the treatment space,
the closed position is a position where the upper vessel and the lower vessel relatively move to close the treatment space,
when the upper vessel and the lower vessel are switched in position from the open position to the closed position, the substrate supported by the substrate holder is handed over to the substrate support,
the upper vessel includes:
an upper wall; and
a side wall extending downward from an end of the upper wall,
the first space is a space surrounded by the upper wall and the side wall,
the substrate holder is coupled to the side wall, and
the substrate support includes:
a support plate having a disk shape; and
a first protrusion protruding upward from the support plate,
the plurality of substrate holders is provided and disposed to face each other,
the lower surface of the side wall has an inner region in which the substrate holder is installed and an outer region that contacts an upper surface of the side wall of the lower vessel in the closed position, and
the substrate holder includes:
a fixing rod having a rod shape extending downward from the inner region;
a vertical portion extending downward from the fixing rod and having an arc shape;
a horizontal portion extending inward from an end of the vertical portion; and
a second protrusion protruding upward from the horizontal portion.

19. The substrate processing apparatus of claim 18, wherein in the closed position, the substrate supported by the substrate support is located in the first space, and the substrate holder is located lower than the substrate supported by the substrate support.

20. The substrate processing apparatus of claim 19, wherein when viewed from above, the substrate holder and the substrate support do not overlap each other, and a width of the first space is narrower than a width of the second space.
